(19) United States
(12) Patent Application Publication
(10) Pub. No.: US 2005/0020071 A1
(43) Pub. Date: Jan. 27, 2005

(54) Method and apparatus for cleaning and method and apparatus for etching

(76) Inventors: Jun Sonobe, Tsukuba-shi (JP); Yoshikuni Koruda, Tsukuba-shi (JP); Regis Zils, Tsukuba-shi (JP); Minoru Ino, Tsukuba-shi (JP); Takako Kimura, Tsukuba-shi (JP); Yukinobu Nishikawa, Yokohama (JP)

Correspondence Address: Air Liquide;Intellectual Property Department, 2700 Post Oak Boulevard, Suite 1800, Houston, TX, 77056, US

(21) Appl. No.: 10/485,721

(22) PCT Filed: Jul. 31, 2001
(86) PCT No.: PCT/JP01/06604

(51) Int. Cl. H01L 21/302; H01L 21/461

(52) U.S. Cl. 438/689

(57) ABSTRACT

A cleaning apparatus (30) is connected to a treating chamber (12) of a CVD apparatus (10) for forming a silicon film. The cleaning apparatus (30) has a first, a second, and a third gas sources (32, 34, 36) and a chlorine gas, a fluorine gas, and an inert gas are introduced from the gas sources through FMC (38a, 38b, 38c), respectively, with flow rates controlled independently from one another. Those gases are gathered at a pipe (42) and mixed into a mixed gas. The mixed gas is passed through a heated reactor (44) such as a heat exchanger to thereby react the chlorine gas with the fluorine gas and form a formed gas containing fluorinated chlorine gas such as CIF₃. The formed gas is supplied to the treating chamber (12) through a cooler (46), an analyzer (48) and a buffer (54).

### TECHNICAL FIELD

This invention relates to a cleaning method and apparatus and an etching method and apparatus for semiconductor processing systems wherein said cleaning method and apparatus and said etching method and apparatus use an interhalogen fluorine compound gas (IFCG). Here, semiconductor processing denotes the various processes that are executed in order to fabricate a semiconductor device—or a structure that connects to a semiconductor device—on a treatment substrate through the formation thereon of a semiconductor layer, insulating layer, conductive layer, etc., in a prescribed pattern. Said treatment substrate can be, for example, a semiconductor wafer or an LCD substrate, and the connecting structure can be, for example, a conductor, trace, or electrode.

### BACKGROUND ART

Interhalogen fluorine compound gases, such as CIF₃, are used in semiconductor processing systems to etch treatment substrates and to clean the treating chambers and exhaust pipe systems. For example, CIF₃ (chlorine trifluoride) gas is utilized as a cleaning gas for the CVD equipment that is used to form films of silicon (Si), polysilicon, amorphous silicon, silicon oxide (SiO₂), silicon nitride (Si₃N₄), tungsten silicide (WSi₂), titanium-tungsten (TiW), tantalum oxide (Ta₂O₅), and silicon-germanium (SiGe). An advantage of CIF₃ gas is its ability to react without using a plasma; depending on the particular case, it will react even at ambient temperature.

CIF₃ gas is filled as a high-purity liquefied gas into metal cylinders and is delivered in this form to the user's site. At the user's site, the gas-phase portion of the CIF₃ is withdrawn from the cylinder, is depressurized to the vapor pressure prevailing at the cylinder temperature at this point (or to below this vapor pressure), and is then transported to the particular semiconductor fabrication apparatus.

Since CIF₃ has a low boiling point at 12° C., a precise temperature control must be exercised—in particular when large CIF₃ gas flow rates are required—over the associated pumps and supply conduit system in order to obtain the required quantities of the gas and in order to prevent reliquefaction along the conduit pathways. However, CIF₃ is very corrosive and strongly oxidizing and in particular has a very high reactivity in its liquid phase. This places limitations from a materials standpoint on the ability to heat the pumps and conduits, while at the same time heating the pumps and conduits is also undesirable from a practical standpoint. In addition, the storage and transport of this highly reactive liquefied CIF₃ gas is tightly regulated in the United States and Europe, which places limitations on its range of applications notwithstanding the fact that it is a highly desirable cleaning gas.

In another vein, since very high purity levels are not required when CIF₃ is used as a cleaning gas, instances occur in which the CIF₃ purity required by the user does not match the cost of CIF₃ production. Moreover, depending on the particular process involved, it may be preferable to admix different components, for example, CIF or CIF₅, rather than employ a process gas composed of only CIF₃. Again depending on the particular process involved, it may even be desirable in some cases to make CIF or CIF₅ the main component. At the present time, a means such as the addition of a separate process for producing the process gas is required when it is desired to make these types of adjustments in the gas components as a function of the particular process.

### DISCLOSURE OF THE INVENTION

This invention was developed in view of the problems described above for the prior art. The object of this invention is to provide improvements in the safety, cost, and flexibility of the IFCG-based cleaning methods and apparatuses and IFCG-based etching methods and apparatuses that are used in semiconductor processing systems.

This invention, which achieves the aforesaid object, is essentially characterized by the onsite and on-demand production and supply of IFCG. For the present purposes, onsite means that the IFCG-producing mechanism is combined with the main processing mechanism of the semiconductor processing system. On-demand is taken to mean that the process gas can be supplied in accordance with the timing required by the main processing mechanism and in accordance with any component adjustment required by the main processing mechanism.

A first aspect of this invention is a cleaning method that removes by-product containing material selected from the group consisting of Si, Mo, Ta, W, SiO_{X}, SiN_{X}, SiON, SiC, SiGe, TaSi_{X}, TaO_{X}, WSi_{X}, TiC, TiN, TiW, BN, and indium tin oxide (ITO), that has accumulated in the treating chamber of a semiconductor processing system, wherein said cleaning method is provided with
a process comprising the formation of a mixed gas by mixing the gases afforded by independently introducing a nonfluorine first halogen gas and fluorine gas from, respectively, a first gas source and a second gas source, and selectively introducing inert gas from a third gas source, and
a process in which a product gas containing IFCG is produced by feeding the aforesaid mixed gas into a heated reactor and heating said mixed gas to a temperature at which the first halogen gas and fluorine gas react, and in which said product gas is fed concurrent with its production into the aforesaid treating chamber.

According to a second aspect of this invention, the first halogen gas:fluorine gas:inert gas volumetric ratio in the mixed gas in the method of the first aspect is established at 10-90:10-90:0-90.

According to a third aspect of this invention, in the method of the first or second aspect, the first halogen gas is chlorine gas and the temperature to which the mixed gas is heated by the aforesaid heated reactor is 200° C. to 400° C.

According to a fourth aspect of this invention, the aforesaid inert gas in the method of the first, second, or third aspect is helium.

A fifth aspect of this invention comprises a cleaning apparatus that removes by-product containing material selected from the group consisting of Si, Mo, Ta, W, SiO_{X}, SiN_{X}, SiON, SiC, SiGe, TaSi_{X}, TaO_{X}, WSi_{X}, TiC, TiN, TiW, BN, and ITO, that has accumulated in the treating chamber of a semiconductor processing system, wherein said cleaning apparatus is provided with
an upstream section that forms a mixed gas by mixing the gases afforded by the independent introduction of a nonfluorine first halogen gas and fluorine gas from, respectively, a first gas source and a second gas source, and the selective introduction of inert gas from a third gas source, and
a downstream section that produces a product gas containing IFCG by feeding the aforesaid mixed gas into a heated reactor and heating said mixed gas to a temperature at which the first halogen gas and fluorine gas react, and that feeds said product gas concurrent with its production into the aforesaid treating chamber.

According to a sixth aspect of this invention, the upstream section in the apparatus of the fifth aspect is provided with a controller that can vary the first halogen gas:fluorine gas:inert gas volumetric ratio in the aforesaid mixed gas through independent adjustment of the individual flow rates of the first halogen gas, fluorine gas, and inert gas.

According to a seventh aspect of this invention, the heated reactor in the apparatus of the fifth or sixth aspect is provided with a reaction chamber and an upstream conduit that introduces the aforesaid mixed gas into said reaction chamber, wherein said reaction chamber and said upstream conduit are composed of a highly thermoconductive material that is highly resistant to corrosion by the aforesaid product gas, the aforesaid upstream conduit forms a heat-exchange section by wrapping around the aforesaid periphery, and said heat-exchange section is heated from the periphery by a heater.

An eighth aspect of this invention comprises a method for etching in a semiconductor processing system, that etches a first film on a treatment substrate, said first film substantially comprising material selected from the group consisting of Si, SIPOS (semi-insulating polycrystalline silicon), Ta, and TaSi_{X}, wherein said etching method is provided with
a process comprising the formation of a mixed gas by mixing the gases afforded by independently introducing a nonfluorine first halogen gas and fluorine gas from, respectively, a first gas source and a second gas source, and selectively introducing inert gas from a third gas source, and
a process in which a product gas containing IFCG is produced by feeding the aforesaid mixed gas into a heated reactor and heating said mixed gas to a temperature at which the first halogen gas and fluorine gas react, and in which said product gas is fed concurrent with its production into the aforesaid treating chamber.

According to a ninth aspect of this invention, a second film is present in the method of the eighth aspect on the aforesaid treatment substrate, wherein said second film substantially comprises material selected from the group consisting of SiO₂, SiN_{X}, SiON, TaO_{X}, and photoresists and the aforesaid etching method etches the aforesaid first film selectively relative to the said second film.

A tenth aspect of this invention is an etching apparatus in a semiconductor processing system, that etches a first film on a treatment substrate, said first film substantially comprising material selected from the group consisting of Si, SIPOS, Ta, and TaSi_{X}, wherein said etching apparatus is provided with
a treating chamber that holds the aforesaid treatment substrate,
an upstream section that forms a mixed gas by mixing the gases afforded by the independent introduction of a nonfluorine first halogen gas and fluorine gas from, respectively, a first gas source and a second gas source, and the selective introduction of inert gas from a third gas source, and
a downstream section that produces a product gas containing IFCG by feeding the aforesaid mixed gas into a heated reactor and heating said mixed gas to a temperature at which the first halogen gas and fluorine gas react, and that feeds said product gas concurrent with its production into the aforesaid treating chamber.

According to an eleventh aspect of this invention, the heated reactor in the apparatus of the tenth aspect is provided with a reaction chamber and an upstream conduit that introduces the aforesaid mixed gas into said reaction chamber, wherein said reaction chamber and said upstream conduit are composed of a highly thermoconductive material that is highly resistant to corrosion by the aforesaid product gas, the aforesaid upstream conduit forms a heat-exchange section by wrapping around the aforesaid periphery, and said heat-exchange section is heated from the periphery by a heater.

### BRIEF DESCRIPTION OF THE DRAWINGS

FIG. 1 contains a schematic drawing that illustrates a cleaning apparatus that is an embodiment of the present invention. This cleaning apparatus removes by-product that has accumulated within the treating chamber of a semiconductor processing system.

FIG. 2 contains a schematic drawing that illustrates, as another embodiment of the present invention, an etching apparatus in a semiconductor processing system.

FIG. 3 contains a perspective drawing that illustrates a heated reactor/cooler combined structure that is usable in the apparatuses shown in FIGS. 1 and 2.

FIG. 4 contains a cross-sectional drawing that illustrates the internal structure of the essential features of the heated reactor shown in FIG. 3.

### BEST MODE FOR CARRYING OUT THE INVENTION

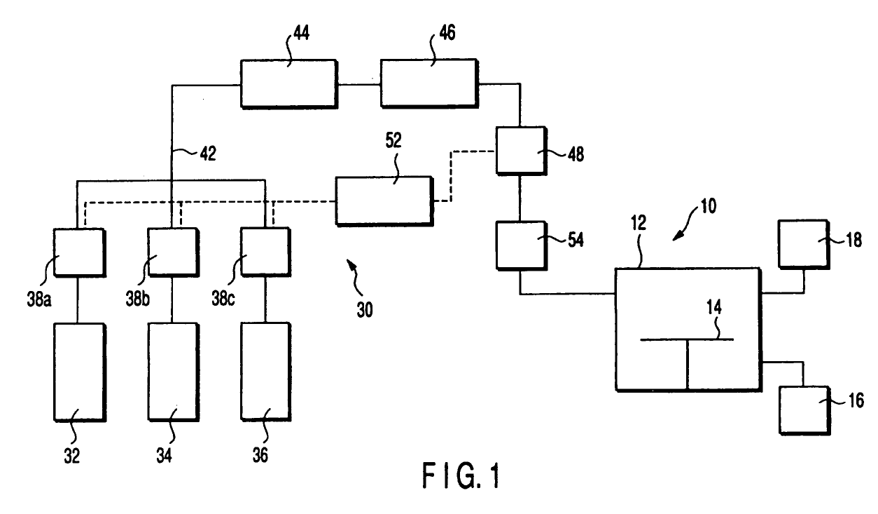

FIG. 1 contains a schematic drawing of a cleaning apparatus that is an embodiment of this invention and that removes by-product that has accumulated within the treating chamber of a semiconductor processing system. This cleaning apparatus 30 may be connected to, for example, a CVD apparatus 10 set up to form a silicon film on a treatment substrate, e.g., a semiconductor wafer or LCD substrate.

The CVD apparatus 10 is provided with a treating chamber 12 that holds the treatment substrate. Disposed within the treating chamber 12 is a platform 14 for mounting the treatment substrate. The lower region of the treating chamber 12 is connected to an exhaust system 16 that exhausts the interior and establishes a vacuum therein. The upper region of the treating chamber 12 is connected to a feed system 18 that supplies process gas, for example, SiH₄.

The repetition of film-forming processes in such a CVD apparatus 10 causes the accumulation of by-product (main component=Si) on the inner walls of the treating chamber 12 and the inner walls of the conduits of the exhaust system 16. The cleaning apparatus 30 in accordance with this invention is used to remove this by-product.

The cleaning apparatus 30 is provided with a first gas source 32, a second gas source 34, and a third gas source 36 in order to supply, respectively, chlorine (Cl₂) gas, fluorine (F₂) gas, and inert gas. The chlorine gas source 32 comprises a cylinder filled with the liquefied gas. Feed of the chlorine gas is relatively easy due to the high vapor pressure involved. The fluorine second gas source 34, on the other hand, comprises a gas generator that produces fluorine gas by electrolysis, although the fluorine gas could also be supplied as a high-pressure gas from a cylinder.

The inert gas functions as a diluent gas or carrier gas, and any inert gas can be used, e.g., helium, argon, nitrogen, and so forth. However, the use of helium with its high thermal conductivity is particularly preferred in order to facilitate heating of the mixed gas, vide infra. Use of the inert gas may be omitted depending on the particular treatment, i.e., introduction of the inert gas is carried out on a selective basis.

The chlorine gas from the first gas source 32, the fluorine gas from the second gas source 34, and the inert gas from the third gas source 36 pass through, respectively, mass flow controller (MFC) 38a, MFC 38b, and MFC 38c, which results in their introduction with their flow rates under separate and independent control. The independently introduced chlorine gas, fluorine gas, and inert gas are combined and mixed in the conduit 42 to form a mixed gas. The chlorine gas:fluorine gas:inert gas volumetric ratio established in this mixed gas should be 10-90:10-90:0-90.

The mixed gas generated in this manner is transported into a heated reactor 44, for example, a heat exchanger, and is heated to 200° C. to 400° and preferably 250° C. to 350° C. This serves to produce a product gas containing chlorine fluoride gas, e.g., CIF₃ gas, through reaction of the chlorine gas and fluorine gas. This product gas, which will contain CIF₃ gas as its main component along with other chlorine fluoride gases (CIF, CIF₅, etc.), by-products, and unreacted gases, is cooled by the cooler 46 to around room temperature—where CIF₃ does not liquefy—and is discharged at a pressure at which the CIF₃ does not liquefy.

The product gas withdrawn from the cooler 46 is first passed through an analyzer 48 that measures the interhalogen fluorine compound. The measurement results afforded by the analyzer 48 are fedback to the main controller 52, and the MFCs 38a, 38b, and 38c are adjusted on the basis of these measurement results. This effects adjustment in such a manner that the chlorine gas:fluorine gas:inert gas volumetric ratio in the mixed gas is brought to the prescribed value.

The flow rate and pressure of the product gas are then adjusted in the buffer 54 so as to compatibilize these parameters with the conditions in the treating chamber 12 of the CVD apparatus 10. After this adjustment the product gas is fed to the treating chamber 12. The buffer 54 can also be executed as a temporary storage section that carries out liquefaction of the product gas and its ensuing re-volatilization. This enables the removal of solids and unreacted volatile gases, gaseous by-products, and impurity gases from the product gas in the buffer 54. The chlorine fluoride gas (e.g., CIF₃ gas) in the product gas fed into the treating chamber 12 reacts with the by-product (main component=Si) that has accumulated on the inner walls of the treating chamber 12 and the inner walls of the exhaust system 16 and thereby debonds same from these inner walls. The debonded by-product becomes entrained in the exhaust flow produced by the action of the exhaust system 16 and is flushed from the CVD apparatus 10.

While the embodiment under consideration involves the combination of the cleaning apparatus 30 with a silicon CVD apparatus 10, chlorine fluoride gas is also effective for the removal of substances other than silicon (silicon includes polysilicon and amorphous silicon). These substances other than silicon can be specifically exemplified by Mo, Ta, W, SiO_{X}, SiN_{X}, SiON, SiC, SiGe, TaSi_{X}, TaO_{X}, WSi_{X}, TiC, TiN, TiW, BN, and ITO. Thus, the cleaning apparatus 30 can be effectively used for the cleaning, inter alia, of CVD equipment and etching equipment in which by-product containing material selected from the aforesaid material group has been produced by the particular primary process implemented in the equipment.

### Experiment

A mixed gas of 30 SCCM chlorine gas, 100 SCCM fluorine gas, and 100 SCCM helium was produced and continuously fed at an internal system pressure of 836 torr into a heated reactor 44 comprising a nickel heat exchanger heated to 250° C. to 350° C. As a result, a product gas was obtained that in the vicinity of the outlet from the heated reactor 44 had a CIF₃ concentration of 10% to 30%, giving a CIF₃ yield of 60% to 80%.

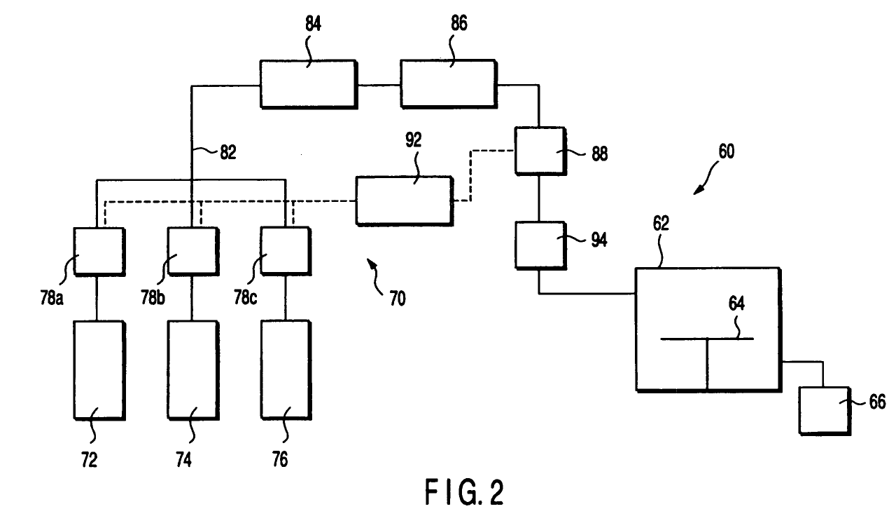

FIG. 2 contains a schematic drawing of an etching apparatus that is another embodiment of this invention, said etching apparatus residing in a semiconductor processing system. This etching apparatus 60 can be used, for example, to etch an Si film on a treatment substrate in preference to an SiO₂ film (selective etching). The treatment substrate can be, for example, a semiconductor wafer or LCD substrate.

The etching apparatus 60 is provided with a treating chamber 62 that holds the treatment substrate. Disposed within the treating chamber 62 is a platform 64 for mounting the treatment substrate. The lower region of the treating chamber 62 is connected to an exhaust system 66 that exhausts the interior and establishes a vacuum therein. The upper region of the treating chamber 62 is connected to a feed system 70 that supplies etching gas. The feed system 70 in the etching apparatus 60 has the same structure as the cleaning apparatus 30 that is illustrated in FIG. 1.

More specifically, this feed system 70 is provided with a first gas source 72, a second gas source 74, and a third gas source 76 in order to supply, respectively, chlorine (Cl₂) gas, fluorine (F₂) gas, and inert gas. The chlorine gas from the first gas source 72, the fluorine gas from the second gas source 74, and the inert gas from the third gas source 76 pass through, respectively, MFC 78a, MFC 78b, and MFC 78c, which results in their introduction with their flow rates under separate and independent control. The independently introduced chlorine gas, fluorine gas, and inert gas are combined and mixed in the conduit 82 to form a mixed gas. The chlorine gas:fluorine gas:inert gas volumetric ratio established in this mixed gas should be 10-90:10-90:0-90.

The mixed gas generated in this manner is transported into a heated reactor 84, for example, a heat exchanger, and is heated to 200° C. to 400° C. and preferably 250° C. to 350° C. This serves to produce a product gas containing chlorine fluoride gas, e.g., CIF₃ gas, through reaction of the chlorine gas and fluorine gas. This product gas, which will contain CIF₃ gas as its main component along with other chlorine fluoride gases (CIF, CIF₅, etc.), by-products, and unreacted gases, is cooled by the cooler 86 to around room temperature—where CIF₃ does not liquefy—and is discharged at a pressure at which the CIF₃ does not liquefy.

The product gas withdrawn from the cooler 86 is first passed through an analyzer 88 that measures the interhalogen fluorine compound. The measurement results afforded by the analyzer 88 are fedback to the main controller 92, and the MFCs 78a, 78b, and 78c are adjusted on the basis of these measurement results. This effects adjustment in such a manner that the chlorine gas:fluorine gas:inert gas volumetric ratio in the mixed gas is brought to the prescribed value.

The flow rate and pressure of the product gas are then adjusted in the buffer 94 so as to compatibilize these parameters with the conditions prevailing in the treating chamber 12 of the CVD apparatus 10. After this adjustment the product gas is fed to the treating chamber 12. The buffer 94 can also be executed as a temporary storage section that carries out liquefaction of the product gas and its ensuing re-volatilization. This enables the removal of solids and unreacted volatile gases, gaseous by-products, and impurity gases from the product gas in the buffer 94. The chlorine fluoride gas (e.g., CIF₃ gas) in the product gas fed into the treating chamber 62 reacts with Si film on the treatment substrate in preference to SiO₂ film on the treatment substrate, thereby etching the former. The etching product becomes entrained in the exhaust flow produced by the action of the exhaust system 66 and is flushed from the etching apparatus 60.

In the embodiment under consideration, the etching apparatus 60 has been styled as an apparatus for etching a first film comprising Si film on a treatment substrate selectively with respect to a second film comprising SiO₂ film. However, chlorine fluoride gas is also effective for the selective etching of material combinations other than the Si film/SiO₂ film combination. Specifically, the first film, i.e., the film that is preferentially etched, can substantially comprise material selected from the group consisting of Si, SIPOS, Ta, and TaSi_{X}. The second film, i.e., the film that is not preferentially etched, can substantially comprise material selected from the group consisting of SiO₂, SiN_{X}, SiON, TaO_{X}, and photoresists.

The cleaning apparatus 30 and the etching apparatus 60 described in the preceding have the ability to both produce and supply chlorine fluoride gas, e.g., CIF₃ gas, at the user's site using chlorine gas, fluorine gas, and inert gas as gas sources. This extinguishes the operational and regulatory problems associated with the supply of chlorine fluoride gas, e.g., CIF₃ gas, to the user's site as a liquefied gas in cylinders. More particularly, the apparatuses 30 and 60 have the ability to adjust the product gas composition in response to the particular process (i) by free variation of the chlorine gas:fluorine gas:inert gas volumetric ratio in the mixed gas over the above-specified range and/or (ii) by free variation of the heating temperature for the mixed gas over the above-specified range.

Other types of interhalogen fluorine compound gases can be generated and supplied by using another halogen gas (other than fluorine) in place of chlorine gas as the gas in the first gas source (32, 72). For example, the use of bromine (Br₂) gas as the gas in the first gas source 32 enables the supply of product gas containing at least 1 of BrF, BrF₃, and BrF₅, while the use of iodine (I₂) gas as the gas in the first gas source 32 enables the supply of product gas containing at least 1 of IF, IF₃, IF₅, and IF₇. An appropriate process pressure and temperature should be selected in correspondence to the source gas used when the production and supply of these other IFCGs is being pursued.

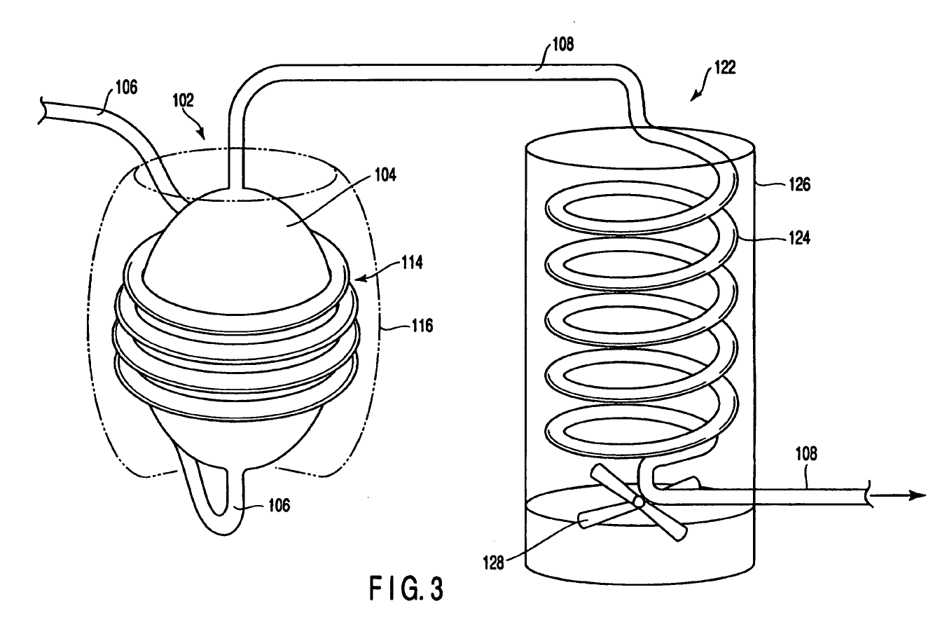

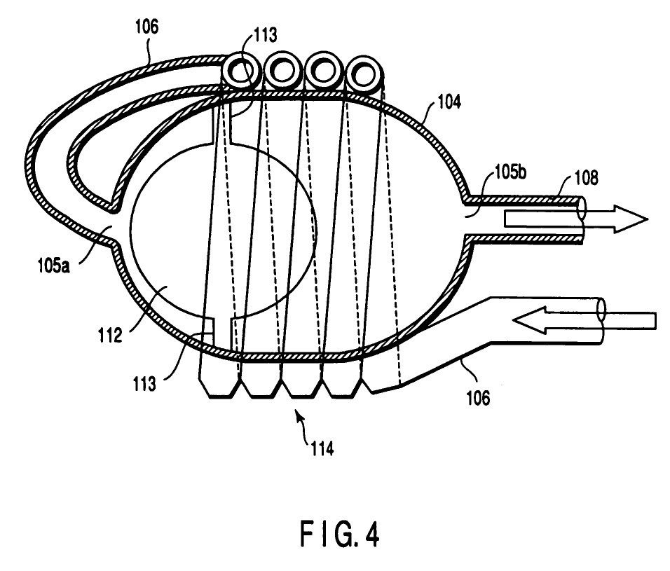

FIG. 3 contains a perspective drawing that illustrates a structure in which a heated reactor 102 and a cooler 122 are combined. FIG. 4 contains a cross-sectional drawing that illustrates the internal structure of the essential features of the heated reactor 102. This heated reactor 102 and cooler 122 can be used for the heated reactor 44 and cooler 46 in the apparatus illustrated in FIG. 1 and for the heated reactor 84 and cooler 86 in the apparatus illustrated in FIG. 2.

The heater 102 is provided with a reaction chamber 104 that is formed by an oval-shaped casing and that has a first port 105a and a second port 105b. The upstream conduit 106 is connected to the first port 105a in order to introduce a mixed gas of chlorine gas, fluorine gas, and inert gas. The downstream conduit 108 is connected to the second port 105b in order to withdraw the gas produced by the reaction chamber 104. A baffle member 112 is disposed within the reaction chamber 104 facing the first port 105a. This baffle member 112 is composed of a spherical element and is fixed by welding through a suitable spacer 113 to the inner surface of the reaction chamber 104. The combination of the oval shape of the reaction chamber 104 and the spherical shape of the baffle member 112 functions to stop the generation of gas drift (gas stagnation) in the reaction chamber 104. The reaction chamber 104, the conduits 106 and 108, the baffle member 112, and the spacer 113 are composed of highly thermoconductive material that is strongly resistant to corrosion by CIF₃, for example, Ni.

The upstream conduit 106 wraps the periphery of the reaction chamber 104 to form a heat exchanger 114. This heat exchanger 114 is also completely enveloped by a jacket heater 116 and is heated from the periphery. The jacket heater 116 comprises an electrically controlled fabric-type heater comprising resistance heating wire embedded in heat-resistant nonwoven fabric.

The cooler 122 is provided with a coil 124 formed by the spiral coiling of the downstream conduit 108. This coil 124 is held within a cylindrical casing 126, and a fan 128 is disposed at the port at the lower end thereof. Thus, the cooler 122 has an air-cooled structure in which the gas in the coil 124 is cooled to around room temperature by the fan.

The integral formation of the heat exchanger 114 on the periphery of the reaction chamber 104 in accordance with the heated reactor 102 illustrated in FIGS. 3 and 4 enables the size of the reactor to be reduced and enables a good thermal efficiency to be obtained.

As has been explained in detail in the preceding, this invention, because it enables the onsite and on-demand supply of IFCG-containing product gas, can improve the safety, cost, and flexibility of the cleaning methods and apparatuses and etching methods and apparatuses in semiconductor processing systems.

1-11. (canceled).

12. A cleaning method that removes a by-product material in a treating chamber of a semiconductor processing system, comprising the steps of:
i) introducing a nonfluorine first halogen gas from a first gas source;
ii) mixing a fluorine gas from a second gas source;
iii) mixing an inert gas from a third gas source;
iv) feeding the mixed gas into a reactor;
v) heating said mixed gas to a temperature at which said first halogen gas and fluorine gas react;
vi) producing an interhalogen fluorine compound gas; and
vii) feeding said compound gas concurrent with its production into said treating chamber.

13. The method according to claim 12, wherein said by-product material comprises at least one component selected from the group consisting of:
a) Si,
b) Mo,
c) Ta,
d) W,
e) SiOₓ,
f) SiNₓ,
g) SiON,
h) SiC,
i) SiGe,
j) TaSiₓ,
k) TaOₓ,
l) WSiₓ,
m) TiC,
n) TiN,
o) TiW,
p) BN, and
q) ITO.

14. The method according to claim 12, wherein said mixed gas comprises said first halogen gas in the range of from about 10% to about 90% by volume, said fluorine gas in the range of from about 10% to about 90% by volume, and said inert gas in the range of from about 10% to about 90% by volume.

15. The method according to claim 12, wherein said first halogen gas is chlorine.

16. The method according to claim 12, wherein the reacting temperature of said mixed gas is in the range of about 200° C. to about 400° C.

17. The method according to claim 12, wherein said inert gas is helium.

18. A cleaning apparatus that removes a by-product material in a treating chamber of a semiconductor processing system that comprises:
i) an upstream section that forms a mixed gas; and
ii) a downstream section that produces an interhalogen fluorine compound gas,
wherein said mixed gas consists of a nonfluorine first halogen gas from a first gas source, a fluorine gas from a second gas source, and an inert gas from a third gas source,
wherein said interhalogen fluorine compound gas is produced by feeding said mixed gas into a reactor and heating said mixed gas to a reacting temperature, and
wherein said compound gas is fed concurrent with its production into said treating chamber.

19. The apparatus according to claim 18, wherein said by-product material comprises at least one component selected from the group consisting of:
a) Si,
b) Mo,
c) Ta,
d) W,
e) SiOₓ,
f) SiNₓ,
g) SiON,
h) SiC,
i) SiGe,
j) TaSiₓ,
k) TaOₓ,
l) WSiₓ,
m) TiC,
n) TiN,
o) TiW,
p) BN, and
q) ITO.

20. The apparatus according to claim 18, wherein said upstream section further comprises:
iii) a controller,
wherein said controller can adjust the individual volumetric flow rates of said first halogen gas, said fluorine gas, and said inert gas.

21. The apparatus according to claim 18, wherein said reactor comprises:
i) a reaction chamber, and
ii) an upstream conduit,
wherein said reaction chamber and said upstream conduit are composed of a thermoconductive material that is resistant to corrosion,
wherein said upstream conduit forms a heat-exchange section by wrapping around the periphery of said reaction chamber, and
wherein said heat-exchange section is heated from the periphery by a heater.

22. An etching method for a semiconductor processing system that etches a first film on a treatment substrate comprising the steps of:
i) introducing a nonfluorine first halogen gas from a first gas source;
ii) mixing a fluorine gas from a second gas source;
iii) mixing an inert gas from a third gas source;
iv) feeding the mixed gas into a reactor;
v) heating said mixed gas to a temperature at which said first halogen gas and fluorine gas react;
vi) producing an interhalogen fluorine compound gas;
vii) feeding said compound gas concurrent with its production into said treating chamber, and
wherein said first film comprises at least one component selected from the group consisting of:
a) Si,
b) POS,
c) Ta, and
d) TaSiₓ.

23. The method according to claim 22, wherein a second film is present on the treatment substrate, and
wherein said second film comprises at least one component selected from the group consisting of:
a) SiO₂,
b) SiNₓ,
c) SiON,
d) TaOₓ, and
e) photoresists.

24. The method according to claim 23, wherein said etching method etches the first film relative to the second film.

25. An etching apparatus for a semiconductor processing system that etches a first film on a treatment substrate, comprising:
i) a treating chamber that holds said treatment substrate;
ii) an upstream section that forms a mixed gas; and
iii) a downstream section that produces an interhalogen fluorine compound gas,
wherein said mixed gas consists of a nonfluorine first halogen gas from a first gas source, a fluorine gas from a second gas source, and an inert gas from a third gas source,
wherein said interhalogen fluorine compound gas is produced by feeding said mixed gas into a reactor and heating said mixed gas to a reacting temperature,
wherein said compound gas is fed concurrent with its production into said treating chamber, and
wherein said first film substantially comprises at least one component selected from the group consisting of:
a) Si,
b) SIPOS,
c) Ta, and
d) TaSiₓ.

26. The apparatus according to claim 25, wherein said etching apparatus comprises:
i) a reaction chamber; and
ii) an upstream conduit,
wherein said reaction chamber and said upstream conduit are composed of a thermoconductive material that is resistant to corrosion,
wherein said upstream conduit forms a heat-exchange section by wrapping around the periphery of said reaction chamber, and
wherein said heat-exchange section is heated from the periphery by a heater.
